(19) United States
(12) Patent Application Publication
(10) Pub. No.: US 2004/0227230 A1
(43) Pub. Date: Nov. 18, 2004

(54) Heat spreaders

(76) Inventor: Ming-Ching Chou, Taichung City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/436,254

(22) Filed: May 13, 2003

(51) Int. Cl. H01L 23/34

(52) U.S. Cl. 257/712; 257/713; 257/717; 257/720

(57) ABSTRACT

A heat spreader has an improved geometry which reduces the mechanical stress due to the thermal expansion to enhance the heat transfer performance, and increases the surface area to reduce the thermal resistance between device and surrounding without external cooling assemblies. The heat spreader is able to improve the electrical performance of power modules due to the improved thermal performance.

### BACKGROUND OF THE INVENTION

1. Field of the Invention

This invention relates to power converters and/or power modules. The main characteristic of this heat spreader is that the heat conducted from power component of the power converter or power module to surrounding or other cooling assemblies is accompanied with low thermal resistance and less mechanical stress.

2. Description of the Prior Art

In the field of thermal management technology, increasing the heat flow and reducing the mechanical stress due to thermal expansion are the most important demands. Basically, surface area of component is desirable as it contacts airflow to transfer the heat from inside to the surrounding. However, the conducted heat flow between component and airflow is limited by the surface area of components, the temperature rise of component is kept in high level to conducts the heat. In order to overcome limitations in poor thermal resistance and high component temperature rise, the prior art has been devised the heat spreader and widely used in power converter or power module as a base plate.

FIG. 1a shows the power module with conventional heat spreaders. The heat has been conducted from an electronic power component D_{E} attached with circuit layer through insulation layer to a high thermal conductivity metal plate. The thermal resistance of power component to environment is reduced result in conduct heat with lower temperature rise.

Conventional heat spreaders reduce the thermal resistance and conduct the heat flow efficiently that the power handling of power module is improved and allows the power module to mount an external cooling assembly by screws or clamps.

Generally, a thin sheet of thermal gap filler is used to compensate the gap and irregular between base plate and external cooling assembly so as to obtain better thermal contact. However, the thermal gap filler is compressed by the force from screws and the compression set of thermal gap filler may be higher at the position located around the screws due to the higher compression force. This compression effect result in the gap filler flows from the location around the mounted screws to other places due to its elastical property. This flowed portion of thermal gap filler may be stacked together and acts as a fulcrum and results in increase of the deflection value of base plate and external cooling assembly due to screw mounting and the thermal contact in the central area becomes worse as shown in FIG. 1b. The maximum heat conduction area is limited about 50% to 80% of total covered area due to this effect. The deflection value of heat spreader become more when the temperature goes high due to the poor thermal conductivity of the un-attached central area. The thermal expansion of heat spreader results in increase of the mechanical stress and deflection value, it may reduce the maximum heat conduction area and increase thermal resistance again and again as show in FIG. 1c. This disadvantage is the major limitation of conventional heat spreader geometry when thinner base plate lower profile power module is required to produce power higher and higher.

FIG. 2a shows the single board power module without heat spreader. Power module is constructed by two sides which mount the components to a multiple layer thick-copper PCB. The heat is conducted from power component through its surface directly and through the multiple layer substrata used as heat spreader to surrounding.

Single board power module takes advantages such as easily to achieve mass-production and involving lower assembly cost, it allows airflow through the space between components may increase the contacted area and results in better air-cooling if the power loss of single board power module is not so high. However, the higher output current is required to power more compact modern applications. The temperature rise of power component is difficult to meet the thermal derating requirement in high output current single board power module due to its poorly thermal distribution property of multiple-layer thick copper PCB. The single board power module can be attached to a metal plate with gap filler and acts as a heat spreader to enhance temperature distribution performance. However, the un-attached side still has high thermal resistance due to the poorly thermal conductivity of multiple layer thick-cooper PCB as shown in FIG. 2b. The advantage of better air-cooling and low module height are no longer existed when the gap filler and metal plate are added to provide the possibility for external cooling assembly mounting. The deflection problem is the same as that of the conventional heat spreader when metal-plated single board power module is used to cooperate with external cooling assembly.

What is the best structure of heat spreader? External cooling assembly mountable, less mechanical stress due to mounting, unify the thermal contact to eliminate the thermal expansion problem and reduce the thermal resistance without external cooling assembly are the most important demands of a heat spreader.

### SUMMARY OF THE INVENTION

The invention utilizes a heat spreader with special geometry to enhance the heat transfer performance and to increase the surface area to reduce the thermal resistance between device and surrounding without external cooling assemblies. Briefly, a typical structure of the special heat spreader consists of a circuit layer, a insulation layer with high thermal conductivity and a highly thermal conductivity metal plate with one side trenched slightly. The circuit layer provides electrical connect function to allow component to be soldered directly and connect to other circuit elements. The high thermal conductivity insulation layer provides an electrical isolated thermal path to transfer the heat from power component to base plate. The highly thermal conductivity metal plate conducts heat generated from power component to expended air contact surface area may reduce temperature rise of power component. The slightly trenched side of metal plate provides extra space to hold “flowed” gap filler due to mounting force. The required torque may be reduced about 50% because the initial contact area is reduced, that means the deflection value is reduced more. Reducing the deflection value of metal plate and external cooling assembly and unifying the thermal contact between base plate and external cooling assembly result in less thermally mechanical stress and good for reliability. The trench can be more deep to have lower thermal resistance and acts as an integrated heat sink and allows it to act as a base plate attached with external cooling assembly to provid multiple thermal management function. This special heat spreader is named as “Sink-Plate” to simplify the description as below.

The Sink-Plate provides optimal thermal managing functions:

It eliminates the thermally-mechanical stress due to mounting force, as, it may have the extra space to hold the “flowed” gap filler; It reduces the thermal resistance without external cooling assembly, as it can be used as an integrated heat sink to provide better thermal performance; It works well and do not require any special process, as it can be widely used with low cost.

### BRIEF DESCRIPTION OF THE DRAWINGS

FIG. 1a shows the power module with conventional heat spreaders;

FIG. 1b shows the deflection effect and stacked gap filler due to mounting force;

FIG. 1c shows the thermal resistance plot of conventional heat spreaders;

FIG. 2a shows the single board power module without heat spreaders;

FIG. 2b shows the single board power module with conventional heat spreaders;

FIG. 3a shows the slightly trenched Sink-Plate;

FIG. 3b shows the trench holding the “flowed” gap filler due to mounting force;

FIG. 3c shows the thermal resistance plot of the slightly trenched Sink-Plate;

FIG. 4 shows the slightly cross-trenched Sink-Plate;

FIG. 5 shows the Sink-Plate with pole grid arrays;

FIG. 6a shows the deep trenched Sink-Plate;

FIG. 6b shows the deep cross-trenched Sink-Plate;

FIG. 7 shows the Sink-Plate with pin grid arrays;

FIG. 8 shows the Sink-Plate with supporting plates;

FIG. 9 shows the Sink-Plate with tower-type fins;

FIG. 10 shows the Sink-Plate with tower-type pole grid arrays;

FIG. 11 shows the Sink-Plate based on insulated metal substrata;

FIG. 12 shows the Sink-Plate based on ceramic substrata;

FIG. 13 shows the Sink-Plate based on multiple layers PCB;

FIG. 14 shows the Sink-Plate based on discrete parts assembly;

FIG. 15 shows the molding formed foil with metal plates used as trenched metal plates, and

FIG. 16 shows the fine pins of fins fitted metal plate used as trenched metal plates.

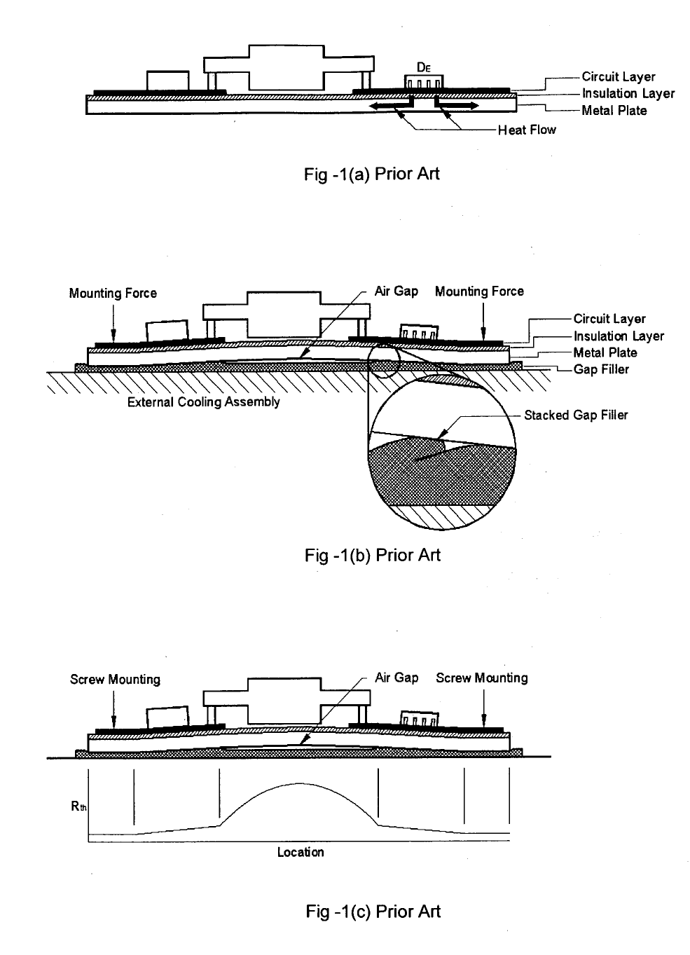

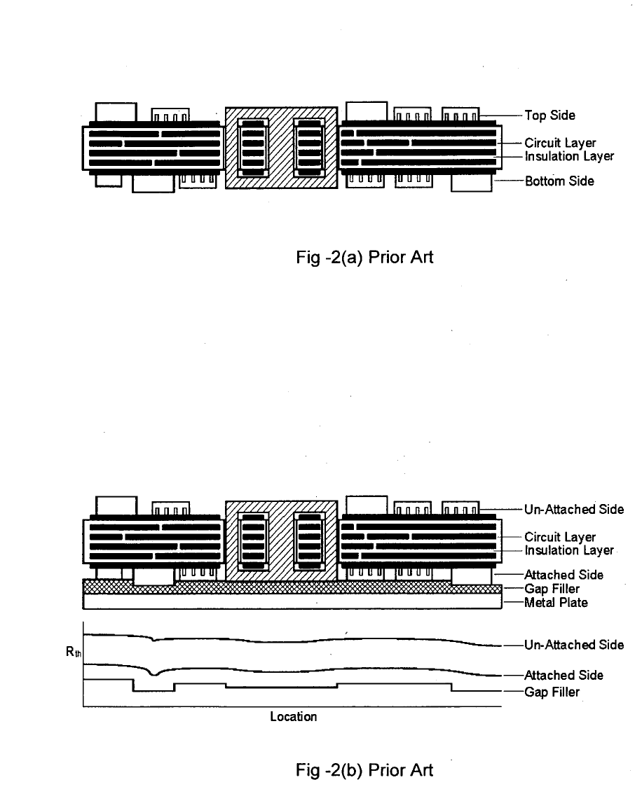

### DETAILED DESCRIPTION OF THE PREFERRED EMBODIMENTS

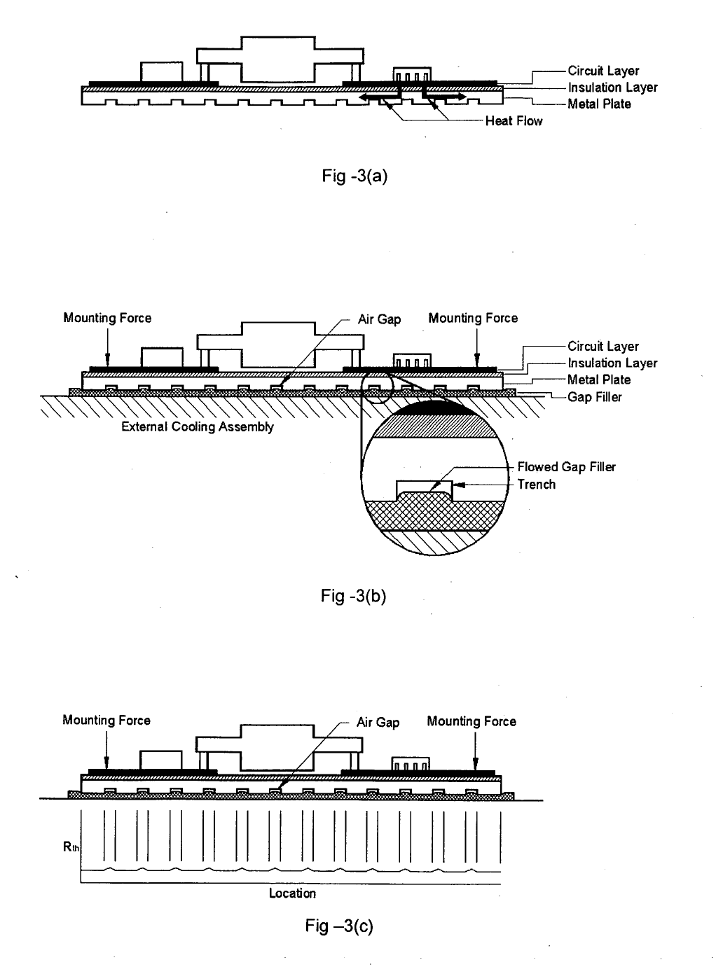

Referring now to the drawings, and more particular to FIG. 3a, a power module implemented with a typical structure of the Sink-Plate is illustrated. A Sink-Plate comprises a circuit layer, a thermal insulation layer, and a highly thermal conductivity base plate with one side trenched slightly. The circuit layer provides electrical connection function; the power component is soldered to this conductor layer directly. The thermal insulation layer provides an electrical isolated thermal path to conduct the heat from the power component to highly thermal conductivity metal plate. The highly thermal conductivity metal plate conducts heat to surrounding or external cooling assembly with very low thermal resistance. Referring to FIG. 3b, the slightly trenched Sink-Plate provides extra space to hold the “flowed” gap filler due to the mounting force. Lower the required torque for screw mounting due to its shorter flow distance of gap filler results in less deflection value and better reliability, and unify the thermal contact between base plate and external cooling assembly. A typical structure of the slightly trenched Sink-Plate with its one dimension thermal resistance plot is shown in FIG. 3c and is different from that of the prior art which is a un-trenched conventional heat spreader with the same of mounting force.

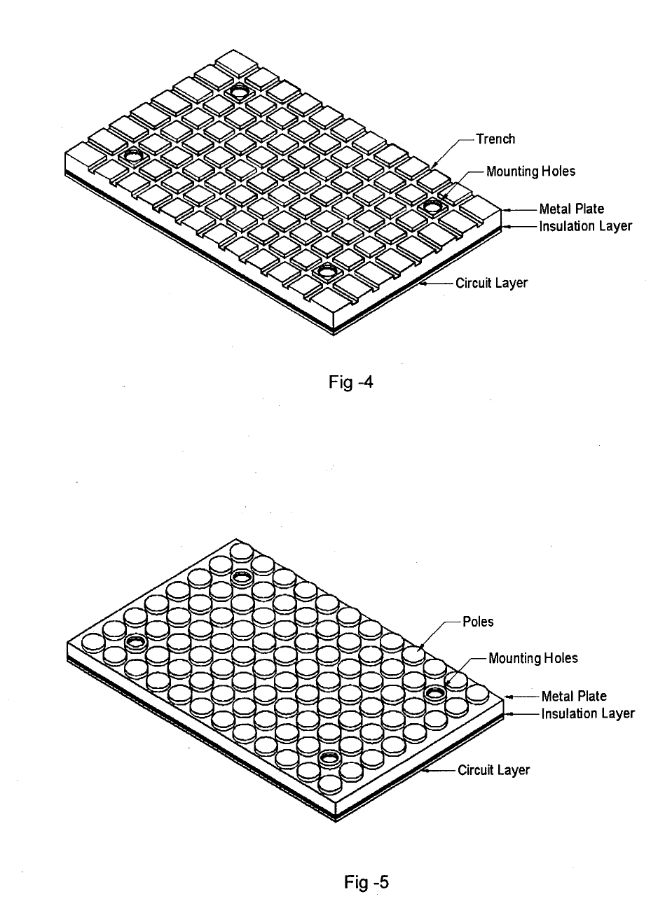

Referring to FIG. 4, during cross-trench process, the Sink-Plate provides extra space distributed on contacted surface to hold the “flowed” gap filler at any directions and this is able to reduce thermally mechanical stress again when the required thermal contact area is larger. The deflection effect due to mounting force and thermally mechanical stress is also reduced by implementing the cross-trenched Sink-Plate.

Referring to FIG. 5, the Sink-Plate may have pole grid arrays to replace cross-trenched surface, the space between poles may be used as the extra space to hold the “flowed” gap filler and act as cross-trenched Sink-Plate which is able to reduce the thermally mechanical stress too. The deflection value due to the mounting force and the thermally mechanical stress is also reduced if the pole grid array Sink-Plate is implemented. It should be noted that reforming the pole and the space between poles by different geometry could derive various shapes of pole grid array type Sink-Plate.

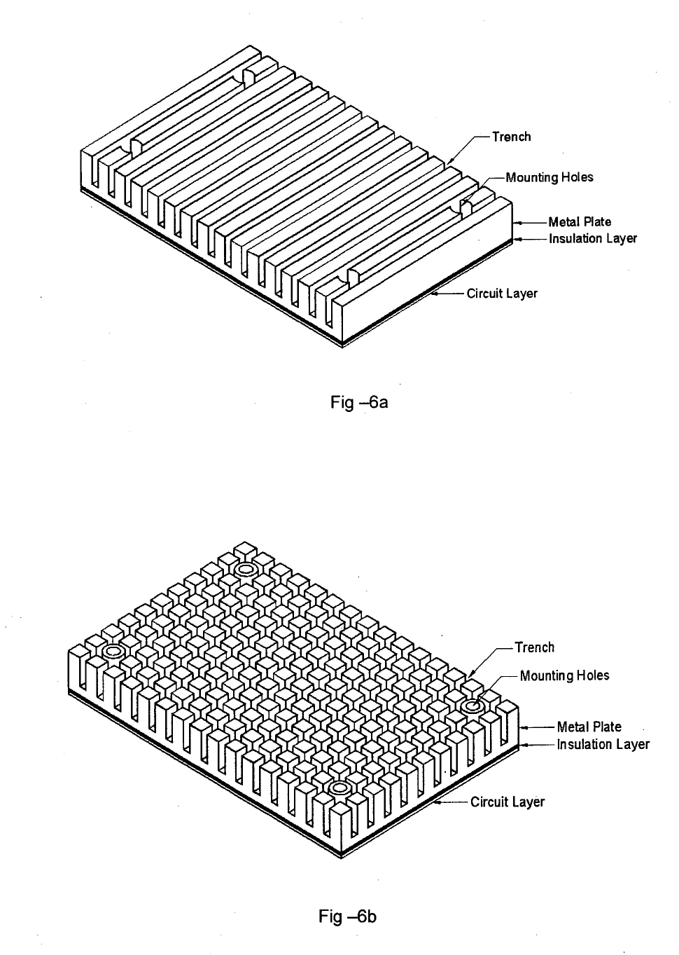

Referring to FIG. 6a, a deep trenched Sink-Plate provides slightly higher of thermal resistance compared with slightly trenched one for conducting heat to external cooling assembly because the length of heat conduct path is a slightly longer due to the deep trenched geometry, but the thermal resistance of free-air cooling or forced-air cooling will be reduced greatly if external cooling assembly is un-attached. For external cooling assembly attached applications, it provides extra space to hold “flowed” gap filler due to compression force of screw mounting, lower the required torque for screw mounting due to its smaller initial contact surface area between the base plate and the gap filler result in less deflection value, and unify the thermal contact between base plate and external cooling assembly. For external cooling assembly un-attached applications, it provides extra surface area to contact airflow and lower the required speed of airflow for specified power dissipation due to its low thermal resistance characteristic. The deep trenched Sink-Plate makes the flexible thermal management with single heat spreader geometry becomes possible. A deep cross-trenched Sink-Plate makes two-direction airflow cooling become possible for better thermal managing function as show in FIG. 6b.

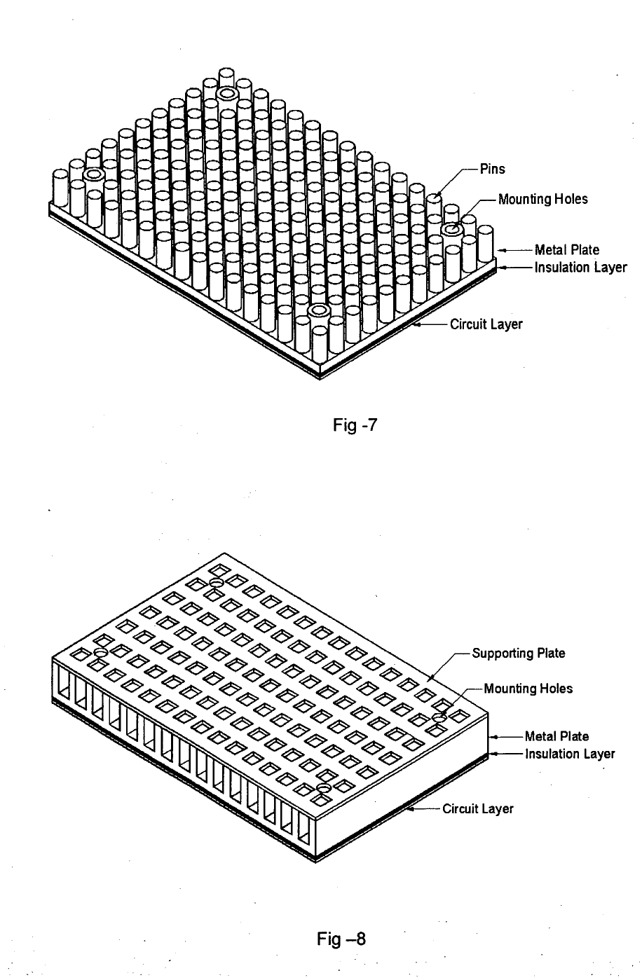

Referring to FIG. 7, the Sink-Plate may have pin grid arrays to replace deep cross-trenched surface, the space between pin may be used as the extra space to hold “flowed” gap filler when external cooling assembly is attached or is used as airflow path to reduce thermal resistance if external cooling assembly is un-attached. The flexible thermal management with single heat spreader geometry becomes possible if pin grid array Sink-Plate is implemented.

For the purpose of enhancing the mechanical strength of deep trenched Sink-Plate or pin grid array Sink-Plate, the supporting plate is used to fix the fins, pins or poles. The supporting plate may have holes to allow airflow to go through it to improve the airflow cooling effect. Any kind of holes in the supporting plate connected with Sink-Plate should be deemed as equivalents as the configuration shown in FIG. 8.

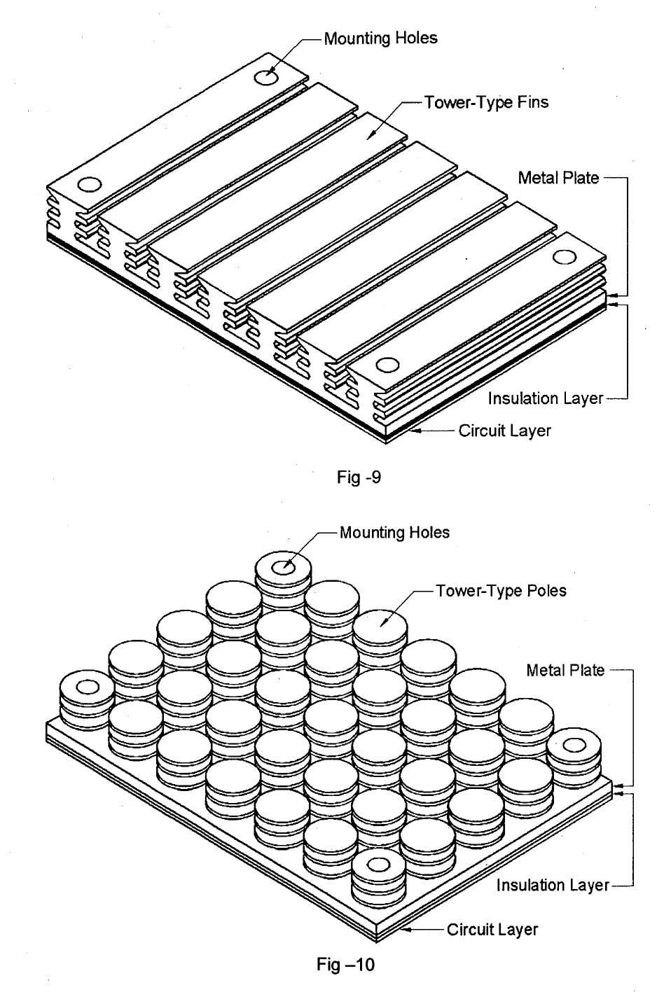

Referring to FIG. 9, the Sink-Plate may have tower-type fins to replace the deep trenched surface to provide better air-cooling effect and better thermal conduction performance without any compromise.

Referring to FIG. 10, the Sink-Plate may have tower-type poles to replace simple pole grid array surface to provide better air-cooling effect and better thermal conduction performance without any compromise.

The idea of Sink-Plate is easy to implement with different technologies and materials.

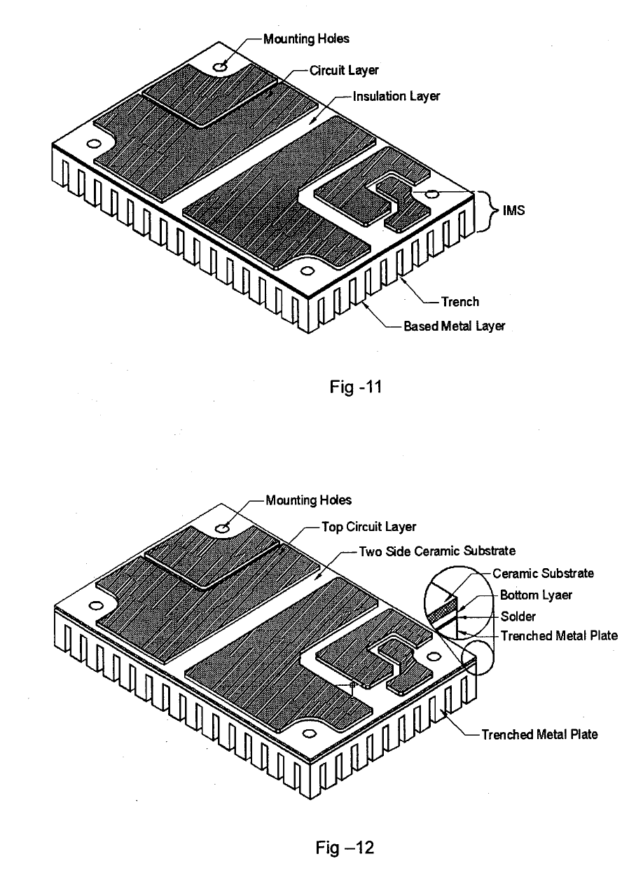

Referring to FIG. 11, the Sink-Plate is implemented based on insulated metal substrate (IMS). The IMS is constructed by stacking and pressing three layers of different material including circuit layer, insulation layer and based metal layer into a single board to produce excellent thermal and electrical performance in the power electronic industry. The circuit layers are formed as a circuit side to solder the component and the Sink-Plate is implemented on the based layer of IMS by using mechanical or chemical trench process to produce required geometry.

Referring to FIG. 12, the Sink-Plate is implemented based on ceramic substrate. The ceramic substrate is covered with two layers of conductor and one of the conductor layers is used as circuit layer to solder the components, the other side is soldered with a metal plate shaped as required geometry.

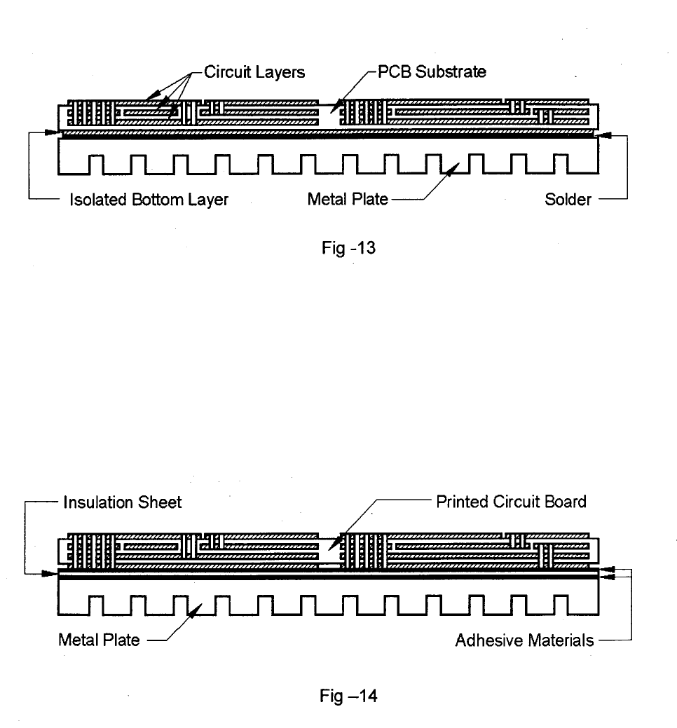

Referring to FIG. 13, the Sink-Plate is implemented based on multiple layers PCB. The multiple layers PCB consists at least two layers of conductor, all of the conductor layers excluding bottom layer are used as circuit layer to solder the power component and provide electrically connect function to connect with other circuit elements, the bottom conductor layer is isolated with other layer by PCB substrate and is able to be soldered with a metal plate shaped as required geometry.

Referring to FIG. 14, the Sink-Plate is implemented based on discrete parts assembly. The printed circuit board is attached with a metal plate shaped as required geometry by an insulation sheet and adhesive materials.

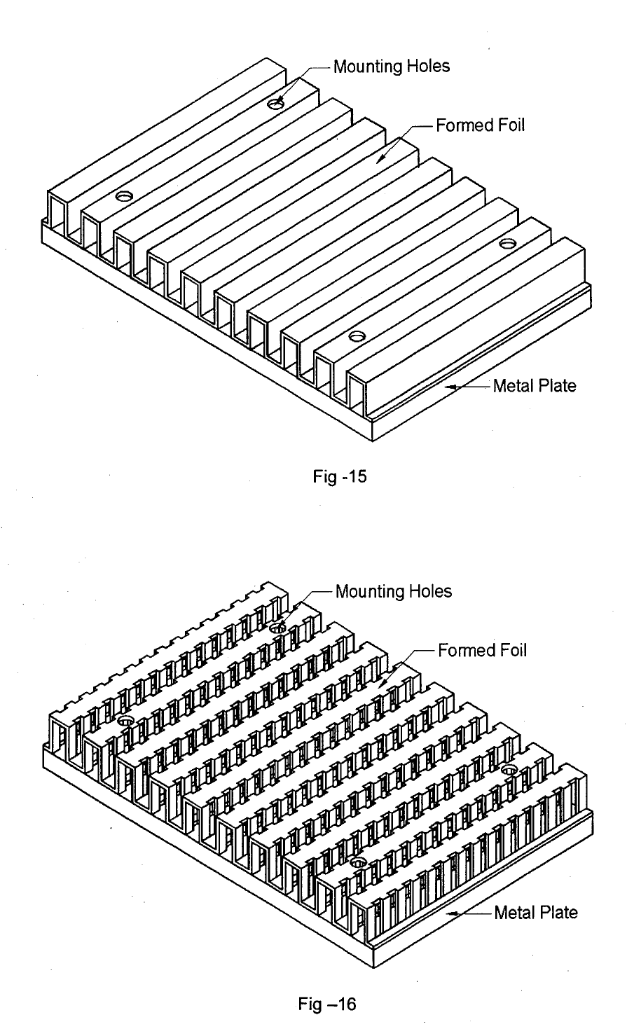

Referring to FIG. 15, molding formed foil attached metal plate may be used as a trenched metal plate. The foil is produced by punch press process and may have very special shape with highly complexity as show in FIG. 16 so as to have extra surface area and allow airflow to go through it at many directions.

A Sink-Plate reduces the bending effect of mechanical stress due to screw mounting, as it unifies the thermal contact between base plate and external cooling assembly and results in less thermally mechanical stress and better in reliability. It provides extra surface area to contact airflow and lower the required speed of airflow for specified power dissipation due to its low thermal resistance characteristic. It makes the flexible thermal management with single heat spreader geometry become possible, as it can be widely used at low cost.

While the invention has been described in terms of a single preferred embodiment, those skilled in the art will recognize that the invention can be practiced with modification within the spirit and scope of the appended claims.

1-13. (canceled).

14. A heat spreader comprises:
a circuit layer;
an insulation layer, and,
a metal plate having a trench in one direction.

15. The heat spreader as claimed in claim 14 wherein said metal plate has a cross trench in a perpendicular direction.

16. The heat spreader as claimed in claim 14 wherein said metal plate has pole grid arrays.

17. The heat spreader as claimed in claim 14 wherein said metal plate has pin grid arrays.

18. The heat spreader as claimed in claim 14 wherein said metal plate has tower-type fins.

19. The heat spreader as claimed in claim 14 wherein said metal plate has tower-type poles.

20. The heat spreader as claimed in claim 14 wherein said circuit layer, said insulation layer and said metal plate are stacked and pressed into a single board.

21. The heat spreader as claimed in claim 14 wherein said metal plate is soldered with two layers ceramic circuit board.

22. The heat spreader as claimed in claim 14 wherein said metal plate is soldered with a multiple-layer printed circuit board.

23. The heat spreader as claimed in claim 14 wherein said metal plate is attached with a multiple-layer printed circuit board by an insulation sheet and adhesive materials.

24. The heat spreader as claimed in claim 14 wherein said metal plate is an un-trenched metal plate attached with a molding formed foil.

25. The heat spreader as claimed in claim 14 wherein said metal plate has a supporting plate attached with trenched side.
